(19) United States
(12) Patent Application Publication
(10) Pub. No.: US 2013/0071992 A1
(43) Pub. Date: Mar. 21, 2013

(54) SEMICONDUCTOR PROCESS

(71) Applicants: Kuo-Hui Su, Taipei City (TW); Yi-Nan Chen, Taipei City (TW); Hsien-Wen Liu, Taoyuan County (TW)

(72) Inventors: Kuo-Hui Su, Taipei City (TW); Yi-Nan Chen, Taipei City (TW); Hsien-Wen Liu, Taoyuan County (TW)

(73) Assignee: NANYA TECHNOLOGY CORPORATION, Taoyuan (TW)

(21) Appl. No.: 13/237,975

(22) Filed: Sep. 21, 2011

(51) Int. Cl. H01L 21/762

(52) U.S. Cl. 438/400; 257/E21.561

(57) ABSTRACT

A semiconductor process is provided. An insulating layer is formed on a semiconductor substrate. A portion of the insulating layer is removed, so as to form a plurality of isolation structures and a mesh opening disposed between the isolation structures and exposing the semiconductor substrate. By performing a selective growth process, a semiconductor layer is formed from a surface of the semiconductor substrate exposed by the mesh opening, so that the isolation structures are disposed in the semiconductor layer.

### BACKGROUND OF THE INVENTION

1. Field of the Application

The invention is related to a semiconductor process.

2. Description of Related Art

With the improvement of semiconductor technology, the size of the semiconductor component is continuously decreased even to the sub-micron. Meanwhile, components further shrink to more minute sizes. Accordingly, the isolation between components becomes a very important issue since the isolation can effectively prevent adjacent components from being short circuited. Nowadays, the most popular method used in the industry is a shallow trench isolation (STI) manufacturing process.

Generally, a shallow trench isolation (STI) is formed by forming a trench in a semiconductor substrate and filling an oxide into the trench to form the isolating layer. However, as the aspect ratio of the trench is increased, the problem occurs in that the oxide is difficult to fill the trench completely. In other words, the voids are generated during the gap-filling of the isolating layer, and the voids are remained in the STI structure. The voids may deteriorate the isolation capacity of the STI structure, thereby causing the current leakage of the device or affecting the device reliability. Therefore, the performance of the semiconductor device is decreased.

### SUMMARY OF THE INVENTION

The invention is directed to a semiconductor process, which is suitable for manufacturing an isolation structure having a high height to width ratio.

The invention is directed to a semiconductor process. An insulating layer is formed on a semiconductor substrate. A portion of the insulating layer is removed, so as to form a plurality of isolation structures and a mesh opening disposed between the isolation structures and exposing the semiconductor substrate. By performing a selective growth process, a semiconductor layer is formed from a surface of the semiconductor substrate exposed by the mesh opening, so that the isolation structures are disposed in the semiconductor layer.

In an embodiment of the invention, a material of the insulating layer includes oxide.

In an embodiment of the invention, the step of removing a portion of the insulating layer includes the followings. A patterned mask layer is formed on the insulating layer. By using the patterned mask layer as a mask, a portion of the insulating layer is removed.

In an embodiment of the invention, a material of the patterned mask layer includes nitride.

In an embodiment of the invention, the step of forming the semiconductor layer includes the followings. The semiconductor layer is formed by the selective growth process, thereby the semiconductor layer filling the mesh opening and covering the patterned mask layer disposed on the isolation structures. By using the patterned mask layer as a stop layer, a planarization process is performed to the semiconductor layer, so as to expose the patterned mask layer. The patterned mask layer is removed.

In an embodiment of the invention, the planarization process includes a chemical mechanical polishing process.

In an embodiment of the invention, a method of removing the patterned mask layer includes a stripping process.

In an embodiment of the invention, a height to width ratio of each isolation structure is larger than 10.

In an embodiment of the invention, a width of each isolation structure is from 20 nm to 30 nm.

In an embodiment of the invention, a height of each isolation structure is from 200 nm to 300 nm.

In an embodiment of the invention, the semiconductor substrate includes an epitaxial silicon substrate.

In an embodiment of the invention, the selective growth process includes a selective silicon growth process.

In an embodiment of the invention, the semiconductor layer includes an epitaxial silicon layer.

In view of the above, in the semiconductor process of the invention, the isolation structures are formed by patterning the insulating layer, and then the semiconductor layer surrounding the isolation structures is formed by the selective growth process. Thus, the isolation structures are disposed in the semiconductor layer. Since the gap-filling step is not required in the formation of the isolation structures in the invention, incomplete gap-filling due to a relative high aspect ratio of the trench is prevented. In other words, the semiconductor process of the invention has simplified steps and is satisfied with the trend of the reduction in the size of the semiconductor devices, and the isolation structure has good isolation capacity. Accordingly, the reliability and the performance of the semiconductor device are improved.

In order to make the aforementioned and other features and advantages of the invention more comprehensible, embodiments accompanying figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIGS. 1A to 1E are schematic top views illustrating a semiconductor process according to an embodiment of the invention.

FIGS. 2A to 2E are schematic cross-sectional views of FIGS. 1A to 1E along the line I-I′.

### DESCRIPTION OF EMBODIMENTS

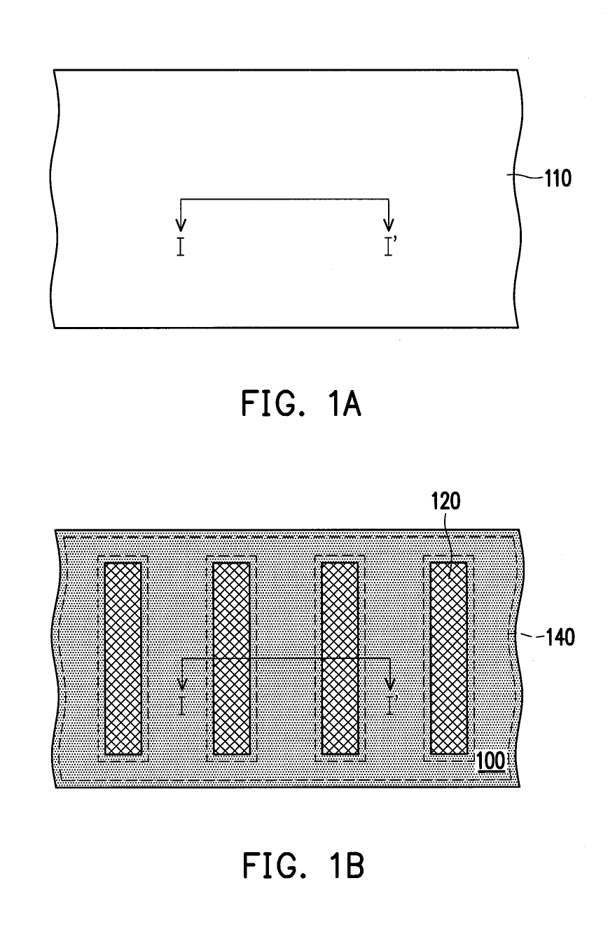

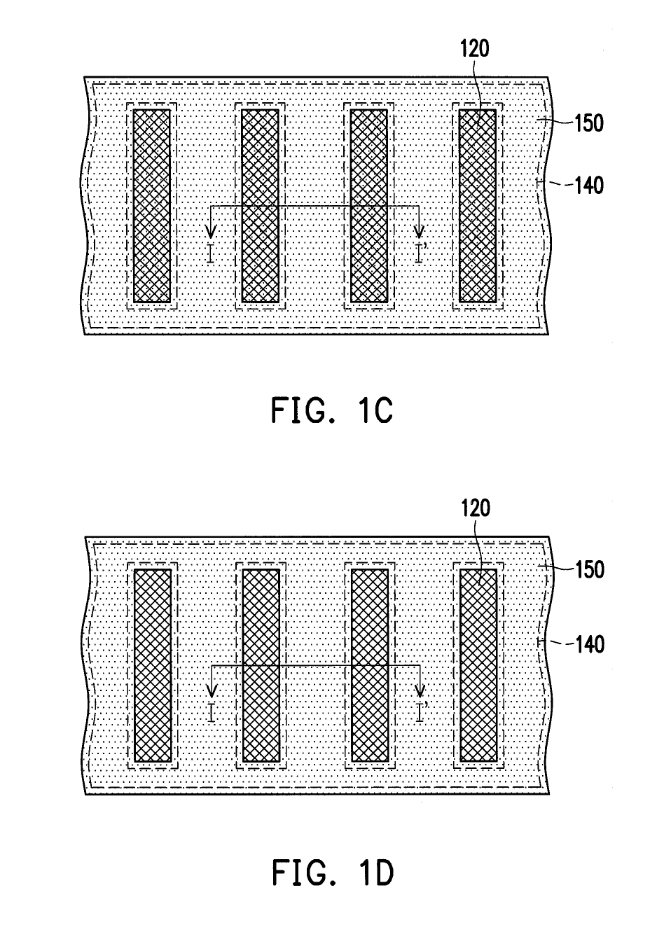

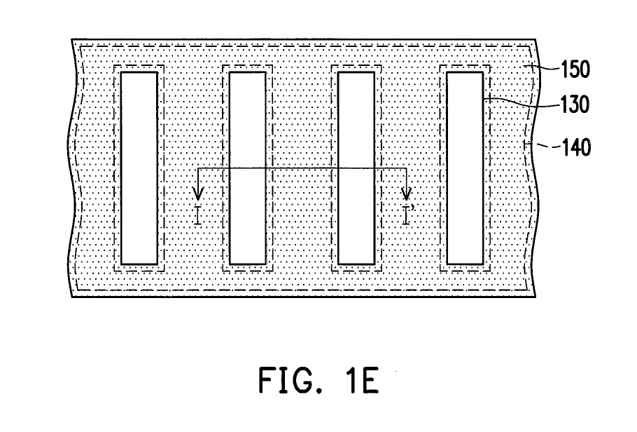

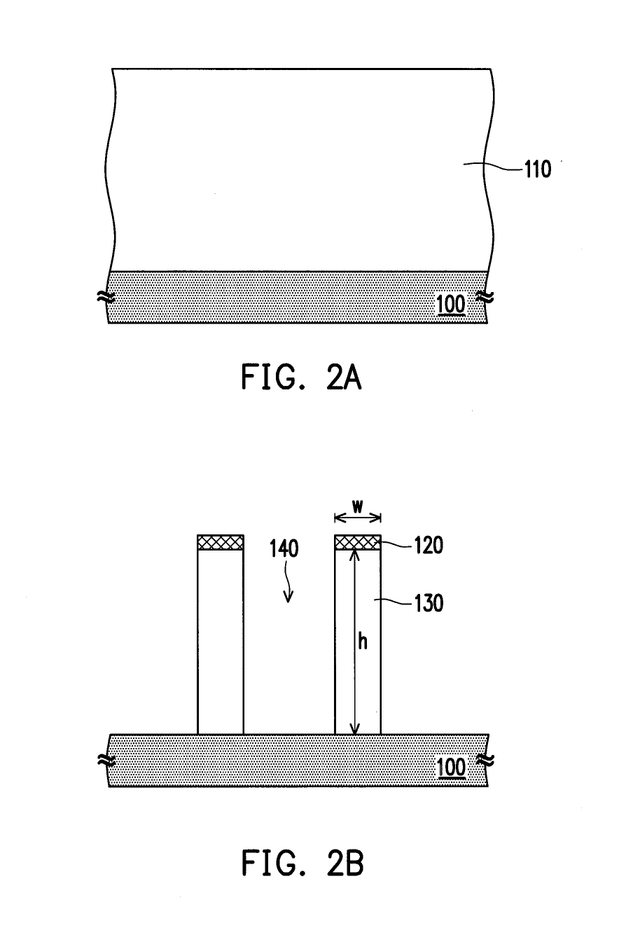

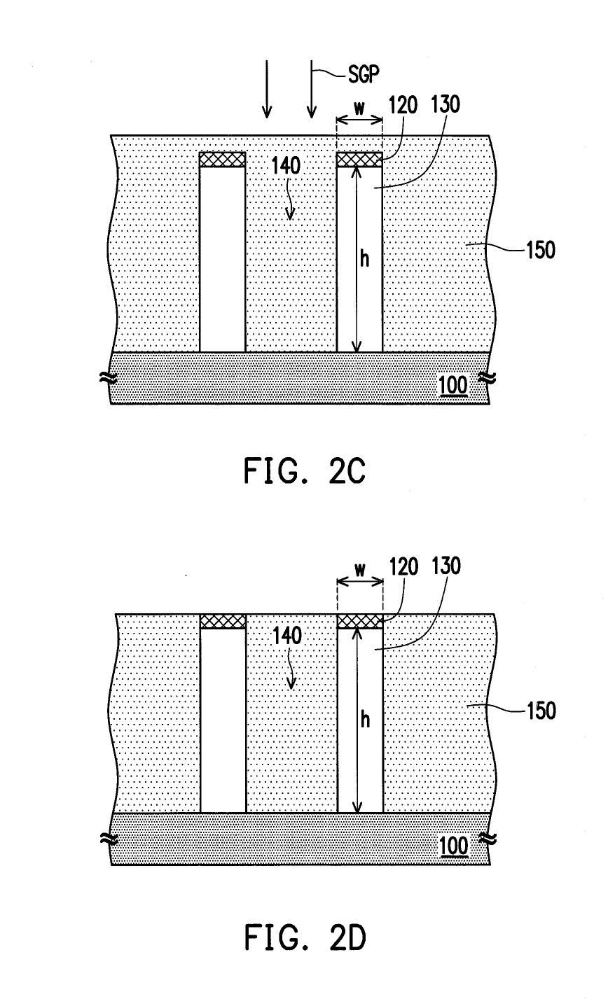

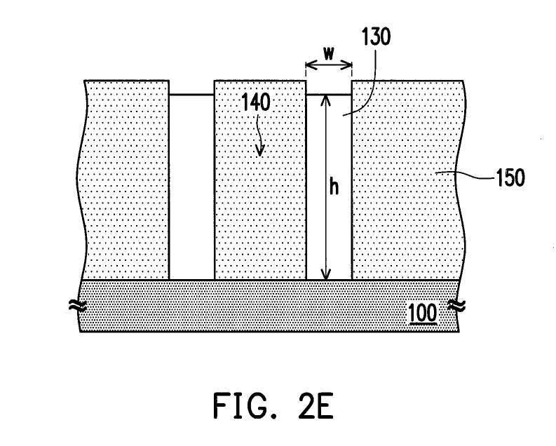

FIGS. 1A to 1E are schematic top views illustrating a semiconductor process according to an embodiment of the invention. FIGS. 2A to 2E are schematic cross-sectional views of FIGS. 1A to 1E along the line I-I′. Referring to FIGS. 1A and 2A simultaneously, firstly, an insulating layer 110 is formed on a semiconductor substrate 100. In the present embodiment, the semiconductor substrate 100 is an epitaxial silicon substrate, for example. A material of the insulating layer 110 is, for example, oxide, and a method of forming the insulating layer 110 is, for example, chemical vapor deposition.

Referring to FIGS. 1B and 2B simultaneously, then, a portion of the insulating layer 110 is removed, so as to form a plurality of isolation structures 130 and a mesh opening 140 disposed between the isolation structures 130 and exposing the semiconductor substrate 100. In the present embodiment, the step of removing a portion of the insulating layer 110 includes the followings. A patterned mask layer 120 is formed on the insulating layer 110. Then, by using the patterned mask layer 120 as a mask, a portion of the insulating layer 110 is removed. In other words, the isolation structures 130 are formed by patterning the insulating layer 110. In the present embodiment, a material of the patterned mask layer 120 includes, for example, nitride, and the patterned mask layer 120 includes a plurality of strip patterns, for instance. A method of removing a portion of the insulating layer 110 is, for example, a dry etching process or a wet etching process. In the present embodiment, each of the isolation structures 130 has a high height to width ratio, for instance, larger than 10. For example, a width w of the isolation structure 130 can be from 20 nm to 30 nm, and a height h of the isolation structure 130 can be from 200 nm to 300 nm. The isolation structures 130 are rectangular parallelepipeds, for example. The mesh opening 140 and the isolation structures 130 are complementary shape, that is, the mesh opening 140 is substantially composed of the space disposed between and surrounding the isolation structures 130. In the present embodiment, when viewed from the top, the mesh opening 140 is a region between an inner dash line and an outer dash line shown in FIG. 1B, which is also represented by dots. It is of certainty that the isolation structures 130 and the mesh opening 140 can have other shapes according to other embodiments.

Referring to FIGS. 1C, 1D, 2C and 2D simultaneously, thereafter, by performing a selective growth process SGP, a semiconductor layer 150 is formed from a surface of the semiconductor substrate 100 exposed by the mesh opening 140, so that the isolation structures 130 are disposed in the semiconductor layer 150. In the present embodiment, a method of forming the semiconductor layer 150 includes following steps. As shown in FIGS. 1C and 2C, the semiconductor layer 150 is formed by the selective growth process SGP, thereby the semiconductor layer 150 filling the mesh opening 140 and covering the patterned mask layer 120 disposed on the isolation structures 130. In the present embodiment, the selective growth process SGP is, for example, a selective silicon growth process, and the semiconductor layer 150 is an epitaxial silicon layer, for instance. Then, as shown in FIGS. 1D and 2D, by using the patterned mask layer 120 as a stop layer, a planarization process is performed to the semiconductor layer 150, so as to expose the patterned mask layer 120. In the present embodiment, the planarization process is, for example, a chemical mechanical polishing (CMP) process. It is noted that through the planarization process, the patterned mask layer 120 is not covered by the semiconductor layer 150, so that the isolation structures 130 provides the isolation function to the semiconductor layer 150 and the semiconductor layer 150 has an even surface. In addition, as the semiconductor layer 150 is grown from a surface of the semiconductor substrate 100 by the selective growth process SGP, the semiconductor layer 150 is substantially regarded as an extension of the semiconductor substrate 100. In other words, the semiconductor layer 150 is substantially served as a semiconductor substrate having isolation structures formed therein, and is used to form components in the subsequent processes. A material of the semiconductor layer 150 is, for example, the same as a material of the semiconductor substrate 100. In the present embodiment, the semiconductor substrate 100 can be an epitaxial silicon substrate, and the semiconductor layer 150 can be an epitaxial silicon layer.

Referring to FIG. 1E and 2E simultaneously, the patterned mask layer 120 is removed. In an embodiment, a method of removing the patterned mask layer 120 includes a stripping process. It is mentioned that in the present embodiment, the patterned mask layer 120 is used as a stop layer in the subsequent planarization process of the semiconductor layer 150, and thus the patterned mask layer 120 is removed after finishing the planarization process. However, in other embodiments, the patterned mask layer 120 can be removed after the step of forming the isolation structures 130 as shown in FIG. 1B and 2B. That is, in an embodiment, by adjusting parameters of the selective growth process SGP, the semiconductor layer 150 can be grown between the isolation structures 130 without covering the top of the isolation structures 130. Therefore, the step of planarizing the semiconductor layer 150 can be omitted.

With the continual miniaturization of semiconductor devices, sizes of isolation structures used to isolate the components are also gradually reduced and have a high height to width ratio. Therefore, in the conventional process for fabricating the isolation structures, the problem occurs in that the insulating material is difficult to fill completely the trench having a high aspect ratio, and the voids are generated and remained in the formed STI structure. Accordingly, the reliability and the performance of the semiconductor device are decreased. In the semiconductor process of the present embodiment, the insulating layer 110 on the semiconductor substrate 100 is patterned, so as to form a plurality of isolation structures 130 and the mesh opening 140 disposed between the isolation structures 130 and exposing the semiconductor substrate 100. Then, by utilizing the selective growth process SGP, the semiconductor layer 150 is formed from the surface of the semiconductor substrate 100 exposed by the mesh opening 140. Therefore, the isolation structures 130 are disposed in the semiconductor layer 150 which is extended from the semiconductor substrate 100. In other words, as compared to forming the isolation structures by forming the trenches in the semiconductor substrate and then filling the oxide in the trenches, in the present embodiment, the isolation structures are formed by patterning the insulating layer, and then the semiconductor layer surrounding the isolation structures is formed by the selective growth process. Therefore, the isolation structures are disposed in the semiconductor layer. Accordingly, the semiconductor layer having isolation structures formed therein is substantially served as a semiconductor substrate used to form components in the subsequent processes. In the semiconductor process of the present embodiment, the isolation structure is not formed by filling the insulating material to the trench, and therefore incomplete gap-filling of the trench with a relative high aspect ratio is prevented. Accordingly, it is also prevented that the reliability and the performance of the semiconductor device is decreased due to the voids generated in the isolation structure. In other words, in the semiconductor process of the present embodiment, the isolation structures having a high height to width are formed by simplified steps and have complete structure. Therefore, the semiconductor process of the present embodiment is satisfied with the trend of the reduction in the size of the semiconductor devices, and the isolation structure has good isolation capacity. Accordingly, the reliability and the performance of the semiconductor device are improved.

In summary, in the semiconductor process of the invention, the insulating layer on the semiconductor substrate is patterned, so as to form a plurality of isolation structures and the mesh opening disposed between the isolation structures and exposing the semiconductor substrate. Then, by utilizing the selective growth process, the semiconductor layer is formed from the surface of the semiconductor substrate exposed by the mesh opening. Therefore, the isolation structures are disposed in the semiconductor layer which is extended from the semiconductor substrate. Accordingly, the semiconductor layer having isolation structures formed therein is substantially served as a semiconductor substrate used to form components in the subsequent processes. Since the gap-filling step is not required in the formation of the isolation structures in the invention, incomplete gap-filling due to a relative high aspect ratio of the trench is prevented. Accordingly, the semiconductor process of the invention has simplified steps and is satisfied with the trend of the reduction in the size of the semiconductor devices, and the isolation structure has good isolation capacity. Therefore, the reliability and the performance of the semiconductor device are improved.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A semiconductor process, comprising:
forming an insulating layer on a semiconductor substrate;
removing a portion of the insulating layer, so as to form a plurality of isolation structures and a mesh opening disposed between the isolation structures and exposing the semiconductor substrate; and
performing a selective growth process to form a semiconductor layer from a surface of the semiconductor substrate exposed by the mesh opening, so that the isolation structures disposed in the semiconductor layer.

2. The semiconductor process as claimed in claim 1, wherein a material of the insulating layer comprises oxide.

3. The semiconductor process as claimed in claim 1, wherein the step of removing a portion of the insulating layer comprises:
forming a patterned mask layer on the insulating layer; and
by using the patterned mask layer as a mask, removing a portion of the insulating layer.

4. The semiconductor process as claimed in claim 3, wherein a material of the patterned mask layer comprises nitride.

5. The semiconductor process as claimed in claim 3, wherein the step of forming the semiconductor layer comprises:
forming the semiconductor layer by the selective growth process, thereby the semiconductor layer filling the mesh opening and covering the patterned mask layer disposed on the isolation structures;
by using the patterned mask layer as a stop layer, performing a planarization process to the semiconductor layer to expose the patterned mask layer; and
removing the patterned mask layer.

6. The semiconductor process as claimed in claim 5, wherein the planarization process comprises a chemical mechanical polishing process.

7. The semiconductor process as claimed in claim 5, wherein a method of removing the patterned mask layer comprises a stripping process.

8. The semiconductor process as claimed in claim 1, wherein a height to width ratio of each isolation structure is larger than 10.

9. The semiconductor process as claimed in claim 1, wherein a width of each isolation structure is from 20 nm to 30 nm.

10. The semiconductor process as claimed in claim 1, wherein a height of each isolation structure is from 200 nm to 300 nm.

11. The semiconductor process as claimed in claim 1, wherein the semiconductor substrate comprises an epitaxial silicon substrate.

12. The semiconductor process as claimed in claim 11, wherein the selective growth process comprises a selective silicon growth process.

13. The semiconductor process as claimed in claim 11, wherein the semiconductor layer comprises an epitaxial silicon layer.
